(19) United States
(12) Patent Application Publication
(10) Pub. No.: US 2019/0141453 A1
(43) Pub. Date: May 9, 2019

(54) DIFFERENTIAL SPEAKER APPARATUS HAVING MOTION FEEDBACK FUNCTION

(71) Applicant: Joong Bae KIM, Daejeon (KR)

(72) Inventors: Joong Bae KIM, Daejeon (KR); Mi Jung SONG, Daejeon (KR); Ye Lin KIM, Daejeon (KR); Yu Jin KIM, Daejeon (KR)

(73) Assignee: Joong Bae KIM, Daejeon (KR)

(21) Appl. No.: 16/098,094

(22) PCT Filed: May 26, 2017
(86) PCT No.: PCT/KR2017/005490

§ 371 Date: Oct. 31, 2018

(30) Foreign Application Priority Data
May 30, 2016 (KR) 10-2016-0066384

(51) Int. Cl. H04R 9/04; H04R 3/08; H04R 7/12; H04R 9/02; H04R 1/40

(52) U.S. Cl. CPC H04R 9/041; H04R 3/08; H04R 7/12; H03F 3/20; H04R 9/027; H04R 1/403; H04R 2209/041; H04R 9/046

(57) ABSTRACT

The present invention relates to a speaker apparatus for reproducing a sound from an electrical signal and, more specifically, to a voice coil speaker apparatus capable of reproducing a high-fidelity sound over a wide frequency band.

### TECHNICAL FIELD

The present invention relates to a speaker apparatus configured to reproduce sound from an electrical signal, and more particularly to a voice coil speaker apparatus capable of reproducing sound with high fidelity over a wide frequency band.

### BACKGROUND ART

The audible frequencies of sound that people can hear with their ears are known to range from about 20 Hz to about 20 kHz. A high fidelity (Hi-Fi) audio system is a system that provides a uniform frequency response with no distortion of the original sound in the entire audio frequency band in reproducing sound corresponding to an audio signal recorded in the form of an electrical signal. However, a typical voice coil type speaker unit uses a mechanical suspension, and thus may produce distorted sound depending on properties of the suspension, leading to low clarity of the reproduced sound and a bad frequency response.

A multi-way speaker system, which is most popular, employs a plurality of speaker units having different features in terms of frequency band in order to achieve a uniform frequency response required in the Hi-Fi audio system. The multi-way speaker system separates an audio signal in frequency bands such as high sound, mid sound, and low sound through a crossover network and reproduces the separated audio signals through speaker units specialized for the respective frequency bands to improve characteristics in terms of frequency response. However, even this speaker system may hardly avoid deterioration of reproduced sound due to the limited properties of each speaker unit, the difference in property between the speaker units and influence according to use of the crossover network and may result in lack of clarity and dynamic range of sound.

As methods to address the intrinsic issues about the speaker units, various techniques have been proposed as follows. To address an issue about the mechanical suspension of the speaker unit, there have been proposed a technique of making the suspension moved only by an electrical signal using a dual or multiple voice coils and a technique of sensing the displacement of a speaker vibration part and feeding back the same to the speaker driving device to form a control loop, thereby making the speaker vibration part move accurately.

In U.S. Pat. No. 3,686,446 titled “PUSH-PULL MOVING COIL HAVING ELECTROMAGNETIC CENTERING MEANS” issued in August 1972, Joseph W. Manger proposed a differential speaker structure with two voice coils. In U.S. Pat. No. 4,360,707 titled “DIGITALLY DRIVEN COMBINATION COILS FOR ELECTRODYNAMIC ACOUSTIC TRANSDUCERS” issued in November 1982, Joel R. Joseph and William F. Bleeke proposed a method of driving a differential speaker apparatus with two voice coils using a digital driving technique of Pulse Width Modulation (PWM).

The differential speaker addresses the issue of a resonance frequency, which is raised in the conventional speaker unit, as a speaker vibration part including voice coils and a diaphragm is moved by electromagnetic force generated by two voice coils alone without depending on mechanical spring force. However, this speaker has a drawback in that a DC current flows through the two voice coils to maintain the balance of force in addition to an AC current corresponding to the audio signal, and there is no practical structure enabling the speaker vibration part to vibrate without being displaced from the center axis of the speaker.

The motion feedback control technology is a method to improve the bass reproduction effect and reduce distortion of reproduced sound by attaching a sensor operable to sense motion of the vibration part of a speaker apparatus and controlling a driving signal by feeding back the motion signal sensed by the sensor to the speaker driving circuit.

However, reproducing bass with a sufficient volume requires the diameter of the speaker unit to be large, and it is well-known that such a large-diameter speaker apparatus has a limit as it deteriorates characteristics of high-frequency sound. Therefore, a Hi-Fi speaker system commonly employs a separate speaker apparatus dedicated to high-frequency sound and mid-frequency sound even if a woofer adopting the motion feedback technology is used.

### DISCLOSURE

### Technical Problem

Therefore, the present invention has been made in view of the above problems, and it is one object of the present invention to provide a high-performance, high-quality speaker apparatus capable of reproducing sound close to original sound in the entire audible frequency band, more specifically, a differential speaker apparatus having a motion feedback function with an improved sound reproduction capability in terms of, for example, reproduced frequency band, and accuracy and clarity of reproduced sound. To this end, the present invention excludes the mechanical suspension structure provided to a conventional speaker apparatus, and provides a speaker apparatus having a structure capable of making the maximum vibration displacement of the speaker vibration part larger than that of a conventional speaker apparatus such that bass of a high output power can be reproduced even by a small-diameter speaker apparatus, a structure capable of smoothly reproducing high frequency sound even with a large-diameter speaker apparatus, and a displacement sensor capable of accurately sensing the vibration displacement of a speaker diaphragm.

### Technical Solution

In order to achieve the above-mentioned object, a magnetic circuit having two magnetic air gaps is constituted by a permanent magnet, two plates, and a pole piece. When two voice coils wound around one bobbin are positioned in each of the two magnetic air gaps created by the magnetic circuit and different currents are applied to the voice coils, the directions of the generated forces are determined by the direction of the currents and the direction of the magnetic field. Therefore, the movement direction and strength of the bobbin are determined by the difference between or sum of the two forces. When the directions of the forces generated in the two voice coils are opposite to each other and the magnitudes of the forces are the same, the bobbin stops in that position.

In driving the two voice coils, the outputs of two amplifiers should be connected to the two voice coils each such that the forces act in opposite directions to maintain balance between the forces. In one voice coil of the two voice coils, an audio signal to be reproduced is directly driven through one amplifier. In the other voice coil, the audio signal is compared with the output of a displacement sensor detecting actual movement of the bobbin and the difference between the two signals is fed back to adjust the output of the other amplifier. Thereby, movement of the bobbin accurately matching the audio signal may be generated.

A speaker system of a differential driving type using such a dual voice coil cannot employ a mechanical suspension, namely a damper and an edge structure used in a conventional voice coil-type speaker apparatus to make a vibration part of the speaker move accurately along a center axis of the speaker. In order to address this issue, the present invention is configured by forming a frame structure of a rectangular instead of a circular shape, and by attaching the vibration part to the four faces of the rectangular frame of the speaker using frictionless and elastic minimized hinge structure as shown in FIG. 6, the vibration part moves only along the center axis of the speaker. In addition, the hinge structure is formed to have a minimized elasticity such that the vibration part of the speaker is hardly influenced by the hinge structure to move, and is vibrated only by the forces generated by the voice coils.

In addition, in the proposed speaker structure, to address the interference caused by the sound waves generated from the rear surface of the diaphragm to the sound waves from the front surface, a wing having a cylindrical structure is provided to the outer periphery of the diaphragm to minimize interference. The wing of the diaphragm is connected to the bobbin with the vibration part support such that the movement of the bobbin is transmitted to the center of the diaphragm and the wing simultaneously. This structure of the diaphragm serves to prevent standing waves, which occur in a conventional large-diameter speaker in reproducing high-frequency sound. Therefore, it is possible to manufacture a high-quality full-range speaker capable of reproducing a full range of sound from a low frequency to a high frequency with one large-diameter speaker.

As a sensor operable to sense the movement of the vibration part, any sensor capable of obtaining a displacement output at the final stage, such as an optical sensor, an acceleration sensor, a linear variable differential transformer (LVDT), an encoder, and a speed sensor, may be employed

### Advantageous Effects

The conventional voice coil-type speaker apparatus hardly avoids deterioration of sound quality due to the structural issues related to resonance frequency, reproduced frequency bandwidth, and sound pressure level according to frequency, and the like. To address these issues, a differential speaker apparatus has been proposed, which may be expected to reproduce sound close to the original sound and improve sound clarity and accuracy by extending the reproducible frequency bandwidth and improving the frequency response flatness. However, it has not entered the actual manufacturing stage yet. In contrast, the present invention proposes a method of practically manufacturing such a differential speaker apparatus, thereby enabling setup of a Hi-Fi audio system at a relatively low cost and application of a high-quality audio system to a portable device.

### DESCRIPTION OF DRAWINGS

FIG. 1 is a cross-sectional view of a conventional voice coil-type speaker apparatus.

FIG. 2 is a view illustrating the basic principle of operation of a differential speaker apparatus.

FIG. 3 is a cross-sectional view of a speaker apparatus according to an embodiment of the present invention.

FIG. 4 is an exploded view of a speaker apparatus according to an embodiment of the present invention.

FIG. 5 is a view illustrating the principle of an optical displacement sensor module to sense the motion of a diaphragm according to an embodiment of the present invention.

FIG. 6 is a view illustrating a structure of a hinge configured to hold a vibration part of a speaker apparatus on a frame according to an embodiment of the present invention.

FIG. 7 is a partial cross-sectional view of a vibration part according to an embodiment of the present invention.

FIG. 8 is a block diagram according to an embodiment of a driver operable to drive a speaker apparatus of the present invention.

### REFERENCE NUMERALS IN THE DRAWINGS

101: Speaker diaphragm
102: Speaker edge
103: Dust cover
104: Damper (spider)
105: Bobbin
106: Top plate
107: Magnet
108: Pole piece
109: Voice coil
110: Speaker frame
201: Magnet
202: Pole piece
203a, 203b: Upper/lower plate
204: Bobbin
205a, 205b: Voice coil
210a, 210b: Air gap
211: Magnetic field direction
301: Speaker diaphragm
302: Diaphragm wing
303a, 303b: Speaker hinge
304a, 304b: Vibration part support
305: Voice coil bobbin
306a, 306b: Upper/lower plate
307: Magnet
308: Pole piece
309a, 309b: Voice coil
310a, 310b, 310c: Speaker frame
402a, 402b, 402c: Hinge thin film
403a, 403b, 403c, 403d: Hinge body
501: Linear light source
502: Light blocking plate
503, 503a, 503b: Photodiode
504: Light
505: Displacement sensor frame
510: Displacement sensor module
601: Audio signal
602: Pre-amplifier
603a, 603b: Power amplifier
604: Speaker apparatus
605a, 605b: Voice coil
606: Optical displacement sensor
607a, 607b: Current/voltage converter
608: Gain adjustment and filter stage
609, 610: Summation circuit

### BEST MODE

Hereinafter, embodiments of the present invention will be described with reference to the drawings. The present invention is not limited to any of the following embodiments. Various modifications can be made to the embodiments of the present invention on the basis of ordinary technology to which the invention pertains.

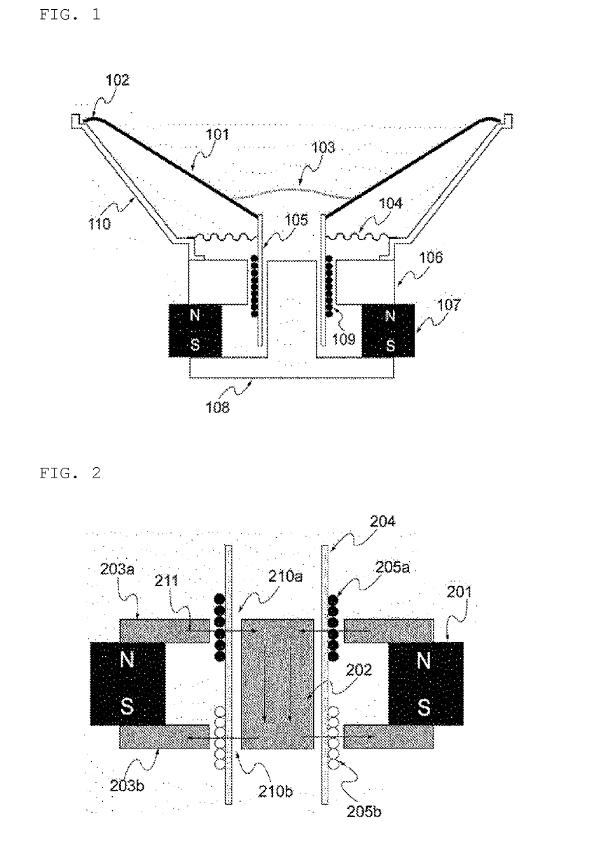

FIG. 1 shows a representative example of the structure of a conventional voice coil-type speaker apparatus. The speaker apparatus in this example has a magnetic circuit including a magnet 107, a pole piece 108 and a top plate 106. When a voice coil 109 wound around the bobbin 105 is positioned in an air gap through which a magnetic field generated between the magnet 107 and the pole piece 108 flows and current flows through the voice coil, Lorentz force is generated, and the voice coil 109 and the bobbin 105 vibrate up and down according to the direction of the current.

The bobbin 105 is supported on a frame 110 by a damper 104, a diaphragm 101 and an edge 102, and is moved accurately in the air gap along a speaker center axis. The damper 104 and the edge 102 have elasticity that constantly pulls the bobbin 105 and the voice coil 109 to the center position. The voice coil is positioned at a position where the force generated by the current flowing through the voice coil and the elastic force of the damper 104 and the edge 102 are balanced.

FIG. 2 is a view illustrating the basic principle of operation of a differential speaker apparatus. When the magnet 201, the pole piece 202 and the two plates 203a and 203b are positioned on the concentric axis to configure the magnetic circuit, two air gaps 210a and 210b are formed, and the magnetic force 211 is directed from the N pole to the S pole of the magnet. In this state, when two independent voice coils 205a and 205b are positioned in the two air gaps 210a and 210b and current is applied to flow therethrough, force is generated in a direction perpendicular to the magnetic field and the current by Fleming's left-hand rule. The direction of the magnetic forces in the two air gaps 210a and 210b are opposite to each other. Therefore, when the currents flow through the two voice coils 205a and 205b in the same direction, forces opposing to each other are generated. Thereby, the two voice coils 205a and 205b and the bobbin 204 around which the two voice coils 205a and 205b are wound are moved up and down together by the difference between the two forces.

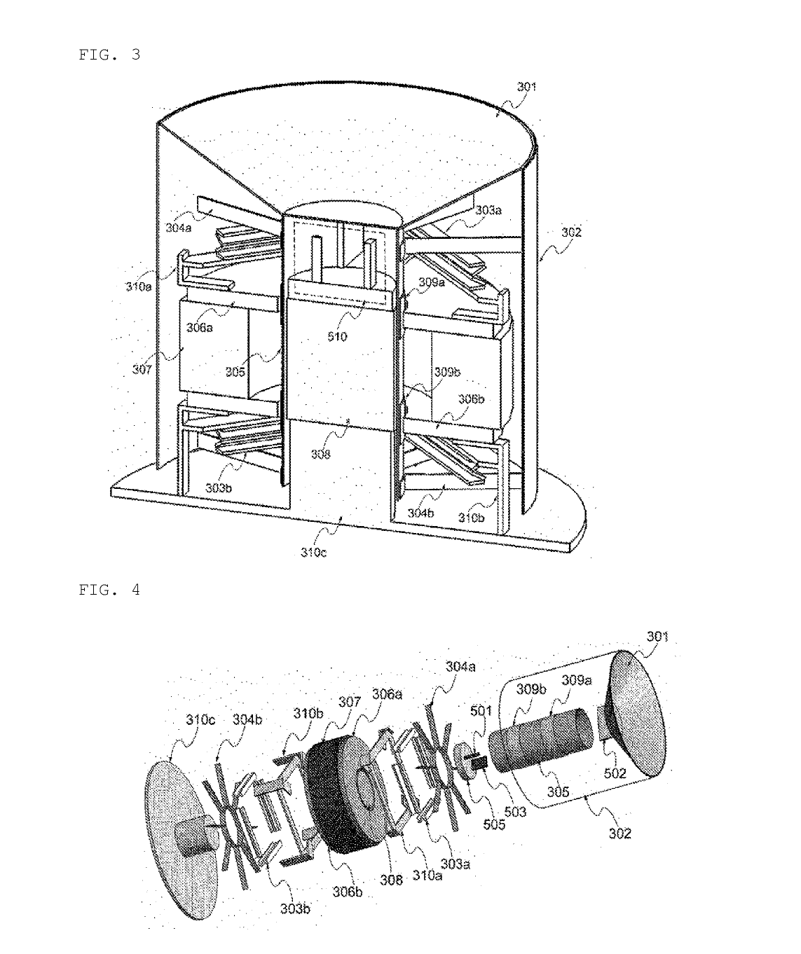

FIG. 3 is a cross-sectional view of a speaker apparatus according to an embodiment of the present invention, and FIG. 4 is an exploded view of a speaker apparatus according to an embodiment of the present invention. The speaker apparatus includes a magnetic circuit including a magnet 307, a pole piece 308 and two plates 306a and 306b, a voice coil bobbin 305 around which two voice coils 309a and 309b are wound so as to be positioned spaced apart from each other in an air gap of the magnetic circuit, two vibration part supports 304a and 304b attached to an outer periphery of the voice coil bobbin 305 to support the voice coil bobbin 305 on speaker frames 310a, 310b and 310c, a diaphragm 301 attached to one side of the voice coil bobbin 305 to vibrate air, a pipe-shaped outer diaphragm wing 302 having one side attached to an outer surface of the diaphragm 301 and an inner side to which the two vibration part supports 304a and 304b are attached, a displacement sensor module 510 operable to sense a vibration displacement of the diaphragm 301, speaker frames 310a, 310b, and 310c fixed to the two plates 306a and 306b and the pole piece 308 to hold the speaker components, hinges 303a and 303b configured to be frictionless and have minimized elasticity and operable to support a vibration part to allow the vibration part to smoothly vibrate while being attached to the external speaker frames 310a and 310b, the vibration part including the voice coil bobbin 305, the voice coils 309a and 309b, the vibration part supports 304a and 304b, the diaphragm 301, and the diaphragm wing 302.

The configuration and the form of the magnetic circuit are not limited to this example. The magnetic circuit may take various forms such as an inner-type and an outer-type. Further, the attachment position and shape of the hinges are not limited to this example.

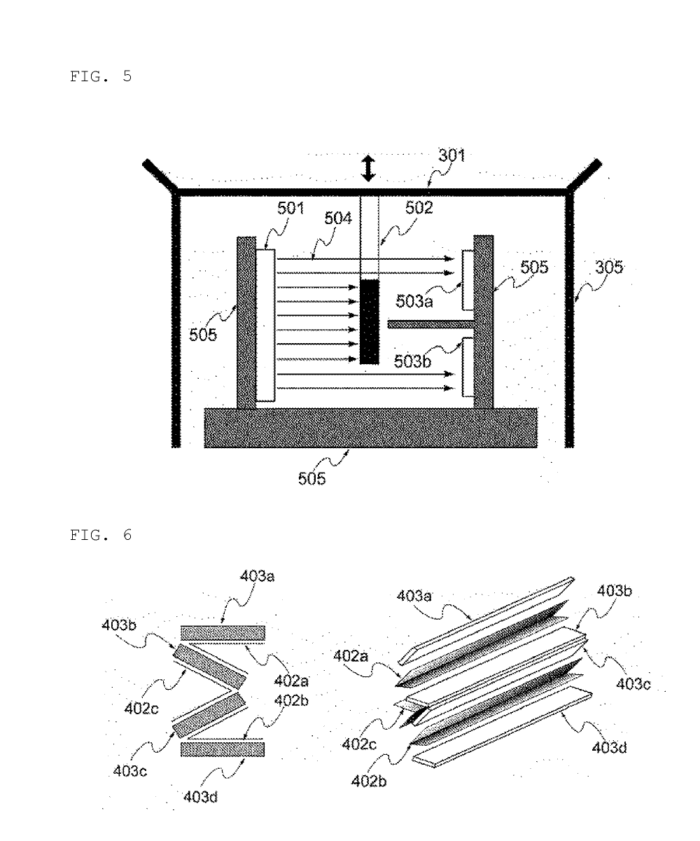

FIG. 5 is a cross-sectional view of an optical displacement sensor according to an embodiment of the present invention. The optical displacement sensor includes a linear light source 501, a light blocking plate 502, and two photodiodes 503a and 503b. The optical displacement sensor operates in a manner that the two photodiodes 503a and 503b sense the amount of light emitted from the linear light source 501. The degree to which the light 504 emitted from the linear light source 501 is blocked is changed according to vertical movement of the light blocking plate 502 attached to the diaphragm 301 of the speaker apparatus, and thus the amount of light reaching the photodiodes 503a and 503b is changed.

The two photodiodes 503a and 503b are attached to a sensor frame 505 having a partition wall so as not to be interfered with the mutual light, and the light blocking plate 502 vibrates at an intermediate position between the two photodiodes 503a and 503b. Accordingly, the amounts of light reaching the two photodiodes 503a and 503b are inversely proportional to each other, and the same amount of light is received at exactly the middle position. That is, the absolute position of the diaphragm 301 can be determined by the difference in output between the two photodiodes 503a and 503b. The output of a photodiode is a current proportional to the amount of light, and a voltage according to the displacement may be extracted through a current/voltage converter circuit.

The displacement sensor module to sense the displacement of the diaphragm can be replaced with various types of sensors such as an acceleration sensor, a linear variable differential transformer, and an encoder in addition to the optical displacement sensor in this embodiment.

FIG. 6 is a cross-sectional view of a hinge configured to hold a vibration part of a speaker apparatus according to an embodiment of the present invention. The hinge includes hinge bodies 403a, 403b, 403c, and 403d formed of four plates and thin films 402a, 402b, and 402c. The thin films 402a, 402b, and 402c are adhered to the four hinge bodies 403a, 403b, 403c, and 403d with the longitudinal sides of the hinge bodies contacting each other, thereby holding the four hinge bodies 403a, 403b, 403c, and 403d such that the four hinge bodies can be folded and unfolded. Therefore, the vibration part supports 304a and 304b connected to one side of the hinge bodies 403a, 403b, 403c, and 403d can move only in one direction with respect to the speaker frame 310. When the hinge bodies are attached to each face of the triangular, rectangular or polygonal speaker frame 310 according to the shape of the frame, the speaker vibration part may accurately vibrate without deviating from the center axis of the speaker.

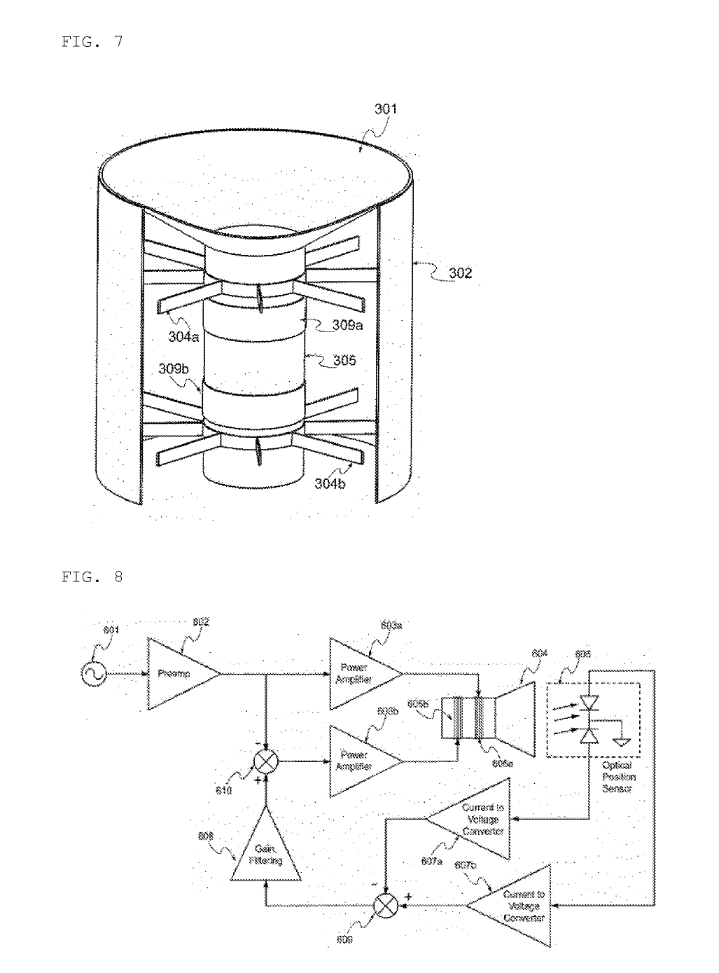

FIG. 7 is a partially cut-away cross-sectional view of a vibration part of a speaker apparatus according to an embodiment of the present invention. The vibration part includes a voice coil bobbin 305 around which two voice coils 309a and 309b are wound, a diaphragm 301 attached to one side of the voice coil bobbin 305, a wing 302 arranged at an outer periphery of the diaphragm 301, and two vibration part supports 304a and 304b configured to connect the voice coil bobbin 305 and the diaphragm wing 302. The diaphragm wing 302 is provided to reduce mutual interference between sound waves emitted from the front surface (outer side) and the rear surface (inner side) of the diaphragm by causing the sound waves to have opposite phases. Further, as the forces generated by the voice coils 309a and 309b are transmitted to the center of the diaphragm 301 through the voice coil bobbin 305 and are transmitted to the outer periphery of the diaphragm 301 through the vibration part supports 304a and 304b and the diaphragm wing 302, standing waves, which occur in the conventional large-diameter speaker, may be prevented from occurring in the high-frequency range.

The shape of the diaphragm is not limited to this example, but the diaphragm may have various shapes such as an elliptical shape and a polygonal shape. When a sound absorbing material is attached to the rear surface of the diaphragm, the intensity of sound waves emitted from the rear surface may be lowered, and thus interference at low frequency may be further reduced.

FIG. 8 is a block diagram according to an embodiment of a driving device operable to drive a speaker apparatus of the present invention. An audio signal 601 is amplified through a preamplifier 602 and a first power amplifier 603a to drive the first voice coil 605a of the speaker apparatus 604. The generated force is determined by the magnitude and direction of the current. The force generated by the first voice coil 605a causes the bobbin 305 and the diaphragm 301 to move as shown in FIG. 3, and the movement of the diaphragm 301 is sensed by the optical displacement sensor 606.

The two output currents of the optical displacement sensor 606 are converted into voltages by the current/voltage converters 607a and 607b, respectively, and supplied to the input of a first summation circuit 609 to obtain the value of difference between the two signals. Here, the output of one current/voltage converter 607a is connected to a negative input terminal of the first summation circuit 609 and the output of the other current/voltage converter 607b is connected to a positive input terminal of the first summation circuit 609. Therefore, the value of difference between the two signals becomes the output of the first summation circuit 609.

The output signal of the first summation circuit 609 is amplified and band-filtered by a gain adjustment and filter stage 608, that is, unnecessary noise is removed, and only a necessary audible frequency band is extracted and then connected to a positive input of a second summation circuit 610. Further, the output of the preamplifier 602 is supplied as a negative input of the second summation circuit 610, and thus the difference between the two inputs becomes the output of the second summation circuit 610. The output of the second summation circuit 610 is amplified by the second power amplifier 603b and then supplied to the second voice coil 605b of the speaker apparatus 604. Here, the output of the second power amplifier 603b is connected such that the direction of the force generated by the second voice coil 605b is opposite to the direction of the force generated by the first voice coil 605a. That is, when the outputs of the two power amplifiers 603a and 603b have the same phase, the directions of forces generated by the two voice coils 605a and 605b are opposite to each other.

More details of the principle of the motion feedback control operation of the speaker driving device are given below. The audio signal 601 drives the first voice coil 605a by the preamplifier 602 and the first power amplifier 603a, and the voice coil causes the speaker diaphragm 301 to move. Here, when the movement of the diaphragm 301 is larger than the audio signal, the difference between the two output currents of the optical displacement sensor 606 becomes larger. Then, the difference between output voltages of the current/voltage converters 607a and 607b and the output voltage of the first summation circuit 609 increases. As a result, the output of the gain adjustment and filter stage 608 and the output of the second summation circuit 610 also increase, which increases the output of the second power amplifier 603b, leading to an increase in the current supplied to the second voice coil 605b and the generated force. Thus, the motion of the diaphragm 301 is reduced. When the motion of the diaphragm 301 becomes smaller than the audio signal, an operation opposite to that of the above example is performed, and eventually a motion of the diaphragm consistent with the audio signal is generated.

### INDUSTRIAL APPLICABILITY

The present invention provides a high-performance, high-quality speaker apparatus capable of reproducing sound close to original sound in the entire audible frequency band, more specifically, a differential speaker apparatus having a motion feedback function with an improved sound reproduction capability in terms of, for example, reproduced frequency band, and accuracy and clarity of reproduced sound. Therefore, the present invention may have a useful application in this field.

1. In a speaker apparatus using magnet and voice coil means, the speaker apparatus comprising:
a magnetic circuit part for applying DC (direct current) magnetic flux to the voice coil, which configured by stacking a magnet, a pole piece, and two plates, thus having two magnetic air gaps in a ring shape;
a speaker frame fixedly attached to the magnetic circuit part;
two voice coils divided into a first voice coil and a second voice coil to apply different currents to the voice coils, respectively;
a voice coil bobbin, the two voice coils being wound around the voice coil bobbin so as to be positioned in the two magnetic air gaps and performing vibrational motion according to a difference between forces generated by currents applied to the two voice coils;
a diaphragm bonded to one side of the voice coil bobbin to convert the vibrational motion of the voice coils into vibration of air to generate sound;
a displacement sensor module to sense the vibration displacement of the diaphragm for feedback to a driving device;
a vibration part support attached to an outer periphery of the voice coil bobbin to support the voice coil bobbin on a speaker frame; and
a hinge configured to connect the vibration part support to the speaker frame to allow a speaker vibration part to perform accurate vibrational motion in the magnetic air gaps along a central axis of speaker, the speaker vibration part including the two voice coils, the voice coil bobbin, the vibration part support and the diaphragm.

2. The speaker apparatus according to claim 1, wherein the diaphragm has a cone shape or a pyramid shape such as a quadrangular pyramid or an octagonal pyramid,
the speaker apparatus further comprising:
a diaphragm wing having a cylindrical shape or a polygonal tubular shape such as a rectangular or octagonal shape corresponding to a shape of an outer periphery of the diaphragm.

3. The speaker apparatus according to claim 2, wherein the diaphragm wing and the voice coil bobbin are connected by the vibration part support to cause movement of the voice coil bobbin to be transmitted to a central portion and a peripheral portion of the diaphragm.

4. The speaker apparatus according to claim 3, wherein the vibration part support comprises:
a ring bonded to an outer periphery of the voice coil bobbin; and
eight rectangular plates each having one side radially connected to the ring and an opposite side radially connected to the diaphragm wing, the rectangular plates being arranged such that a short side thereof is arranged in parallel with the voice coil bobbin.

5. The speaker apparatus according to claim 1, wherein the hinge comprises:
hinge bodies formed by four rectangular plates; and
a thin film respectively attached between the four hinge bodies with long sides of the four hinge bodies contacting each other, the thin film being operable to allow the four hinge bodies to be folded and unfolded.

6. The speaker apparatus according to claim 1, further comprising an optical displacement sensor,
wherein the optical displacement sensor comprises:
a linear light source;
two photodiodes adjacent to each other along a vibration axis of the diaphragm; and
a light blocking plate attached to the diaphragm and positioned between the linear light source and the two photodiodes,
wherein the optical displacement sensor is operable to recognize an absolute position of the diaphragm from a difference between outputs of the two photodiodes by causing amounts of light reaching the two photodiodes from the linear light source to change in inverse proportion to each other according to movement of the diaphragm.

7. A driving device operable to drive the speaker apparatus according to claim 6, the driving device comprising:
a preamplifier operable to amplify a weak audio signal and supply the amplified audio signal to a power amplifier; and
a first power amplifier operable to amplify an output of the preamplifier to drive the first voice coil;
two current/voltage converters operable to convert a current of the optical displacement sensor into a voltage;
a first summation circuit operable to calculate a difference between outputs of the two current/voltage converters;
a gain adjustment and filter stage operable to amplify an output of the first summation circuit to an appropriate level and perform a filter function of removing noise;
a second summation circuit operable to calculate a difference between an output of the gain adjustment and filter stage and the output of the preamplifier; and
a second power amplifier operable to amplify an output of the second summation circuit to drive the second voice coil.
